(19) United States
(12) Patent Application Publication
(10) Pub. No.: US 2016/0056763 A1
(43) Pub. Date: Feb. 25, 2016

(54) SWITCHED-CAPACITOR RC OSCILLATOR

(71) Applicant: QUALCOMM Incorporated, San Diego, CA (US)

(72) Inventors: Shitong ZHAO, San Diego, CA (US); Jingxue LU, San Diego, CA (US)

(21) Appl. No.: 14/464,580

(22) Filed: Aug. 20, 2014

(51) Int. Cl. H03B 5/24

(52) U.S. Cl. CPC H03B 5/24

(57) ABSTRACT

An RC oscillator includes a first capacitive element and a second capacitive element and a comparator having a first input, a second input, and an output for outputting an oscillating signal. The oscillator further includes an integrator having a first input, a second input coupled to a reference voltage source, and an output coupled to the second input of the comparator. The oscillator further includes a switch circuit configured to provide a voltage of the first capacitive element to the first input of the comparator in a cycle and a voltage of the second capacitive element to the first input of the comparator in a subsequent cycle. The integrator is configured to sample and to hold the voltage of the second capacitive element continuously in the cycle.

### BACKGROUND

1. Field

The present disclosure relates generally to a resistor capacitor (RC) oscillator, and more particularly, to a switched-capacitor RC oscillator.

2. Background

An RC oscillator generates an oscillating signal at a frequency based on an RC constant. Compared to other types of oscillators, the RC constant (and therefore the frequency) of RC oscillators is easier to adjust compared to other types of RC oscillators. Accordingly, RC oscillators are increasingly in demand in applications such as in wireless communications. For example, a switched-capacitor RC oscillator may be used to generate an oscillating signal for a phase locked loop in a transmitter/receiver of a user equipment (UE).

One type of RC oscillator is the switched-capacitor RC oscillator, which utilizes a plurality of capacitors alternately charged at a constant rate (e.g., based on the RC constant). One or more comparators compare the voltages of the plurality of capacitors to a reference voltage to generate the oscillating signal.

### SUMMARY

Aspects of a switched-capacitor RC oscillator are disclosed. In one aspect, the switched-capacitor RC oscillator includes a first capacitive element and a second capacitive element. A comparator includes a first input, a second input, and an output outputting an oscillating signal. An integrator includes a first input, a second input coupled to a reference voltage source, and an output coupled to the second input of the comparator. A switch circuit is configured to provide a voltage of the first capacitive element to the first input of the comparator in a cycle and a voltage of the second capacitive element to the first input of the comparator in a subsequent cycle. The integrator is configured to sample and hold the voltage of the second capacitive element continuously in the cycle.

Aspects of a method to operate a switched-capacitor RC oscillator are disclosed. A first capacitive element is charged in a cycle. A voltage of a second capacitive element is sampled and held continuously in the cycle. An integration is performed based on the voltage of the second capacitive element and a reference voltage in the cycle. The voltage of the first capacitive element is compared to an output of the integration in the cycle. A first pulse of an oscillating signal is generated based on a result of the comparison in the cycle.

Further aspects of a switched-capacitor RC oscillator are disclosed. The switched-capacitor RC oscillator includes charging means for charging a first capacitive element in a cycle. Integrating means samples and holds a voltage of a second capacitive element continuously in the cycle, and integrates based on the voltage of the second capacitive element and a reference voltage in the cycle. Comparing means compares a voltage of the first capacitive element to an output of the integration in the cycle and for generating a first pulse of an oscillating signal based on a result of the comparison in the cycle.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

FIG. 1 is a functional block diagram of an exemplary switched-capacitor RC oscillator.

FIG. 2 illustrates timing diagrams of the switched-capacitor RC oscillator of FIG. 1.

FIG. 3 is a functional block diagram of an exemplary switched-capacitor RC oscillator.

FIG. 4 is a waveform diagram of an exemplary switched-capacitor RC oscillator.

FIG. 5 is an operation mode diagram of an exemplary switched-capacitor RC oscillator.

FIG. 6 is a circuit diagram of an exemplary switched-capacitor RC oscillator.

FIG. 7 is a timing diagram illustrating the cycles and clocks of an exemplary switched-capacitor RC oscillator.

FIG. 8 is a timing diagram of an exemplary switched-capacitor RC oscillator illustrating the cycles and the voltages of the first capacitive element, the second capacitive element, and the input of the comparator.

FIG. 9 is a circuit diagram of an exemplary integrator.

FIG. 10 is a circuit diagram of an exemplary switch for the current sources.

FIG. 11 is a first portion of a flowchart of the exemplary switched-capacitor RC oscillator for generating an oscillating signal.

FIG. 12 is the second portion of a flowchart of an exemplary switched-capacitor RC oscillator for generating the oscillating signal.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. The term “exemplary” is used herein to mean “serving as an example, instance, or illustration.” Any design described herein as “exemplary” is not necessarily to be construed as preferred or advantageous over other designs.

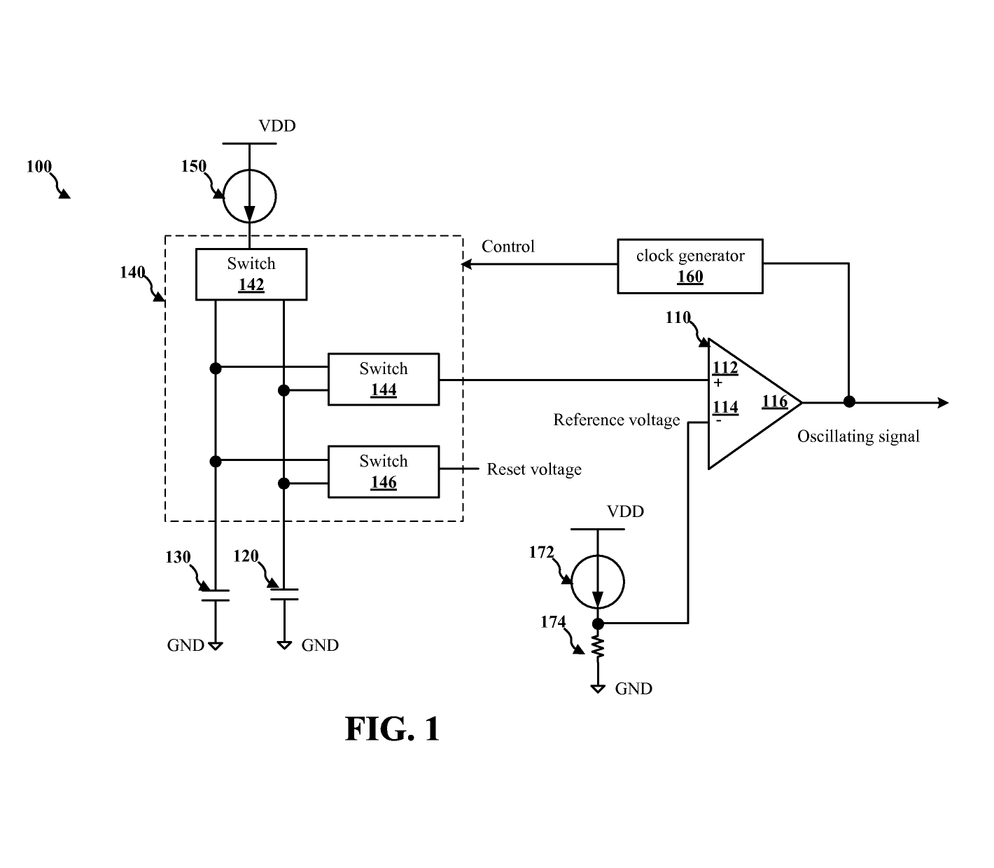

FIG. 1 is a functional block diagram 100 of an exemplary switched-capacitor RC oscillator. The switched-capacitor RC oscillator includes a comparator 110, a first capacitive element (e.g., a capacitor) 120, a second capacitive element (e.g., a capacitor) 130, a switch circuit 140, and a current source 150. The switched-capacitor RC oscillator may further include a clock generator 160. The comparator 110 includes a first input 112, a second input 114, and an output 116. The comparator 110 compares the first input 112 and the second input 114 and outputs an oscillating signal at the output 116 based on the comparison.

Conceptually, the switch circuit 140 may be viewed as including multiple switches 142, 144, and 146. The switch 142 alternately couples the first capacitive element 120 and the second capacitive element 130 to the current source 150. Thus, current source 150 may alternately charge the first capacitive element 120 and the second capacitive element 130. The switch 146 alternately couples the first capacitive element 120 and the second capacitive element 130 to a reset voltage source. The reset voltage may be, e.g., ground (GND). Thus, the first capacitive element 120 and the second capacitive element 130 are alternately discharged.

The switch 144 alternately couples the first capacitive element 120 and the second capacitive element 130 to the first input 112 of the comparator 110. Thus the voltage of the first capacitive element 120 and the voltage of the second capacitive element 130 are alternately provided to the first input 112 of the comparator 110. The second input of the comparator 110 is coupled to a reference voltage from a reference voltage source. In one implementation, the reference voltage may be generated by providing a current to a resistor. For example, the current source 172 provides a current to the resistor 174 to generate the reference voltage. In this fashion, an oscillation frequency of the exemplary switched-capacitor RC oscillator may be adjusted by adjusting a ratio of the impedance of the current source 172 and the resistor 174. The comparator 110 compares the voltage at the first input 112 (the voltage of the first capacitive element 120 or the voltage of the second capacitive element 130) with the reference voltage. In one example, the voltage on the first capacitive element 120 is coupled to the first input 112 of the comparator 110, while the second capacitive element 130 is being discharged. When the voltage of the first capacitive element 120 is charged by the current source 150 to exceed the reference voltage, the comparator triggers and outputs a high level at output 116.

In one configuration, the clock generator 160 receives input from the output 116 of the comparator 110, and generates a control signal or signals for the switch circuit 140. For example, the clock generator 160 may respond to the output 116 going high and generate control signals to cause the switch 144 to switch and to couple the second capacitive element 130 to the first input 112 of the comparator 110. The second capacitive element 130 being previously discharged, the voltage on the first input 112 of the comparator 110 would thus be GND and be lower than the reference voltage. In response, the comparator outputs a low level at output 116, while the current source 150 charges the second capacitive element 130. As the voltage at the second capacitive element 130 reaches the reference voltage, the process repeats, and an oscillating signal is formed at the output 116.

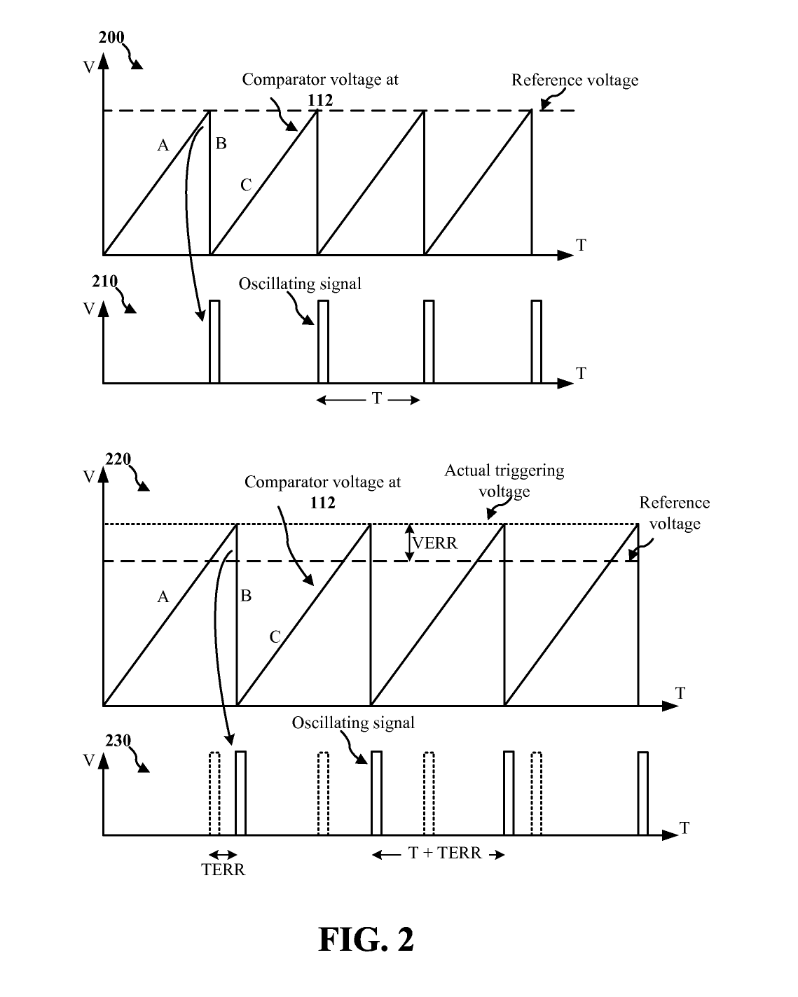

FIG. 2 illustrates the timing diagrams (voltage vs. time) 200, 210, 220, and 230 of the switched-capacitor RC oscillator of FIG. 1. Timing diagrams 200 and 210 represent an ideal case of operation. The timing diagram 200 illustrates the voltage at the first input 112 of the comparator 110, and the timing diagram 210 illustrates the output at the output 116 of the comparator 110 (e.g., the oscillating signal). For example, at A, the first capacitive element 120 is coupled to the first input 112 of the comparator 110 by the switch 144. The current source 150 charges the first capacitive element 120, and therefore the voltage at the first capacitive element 120 is applied to the first input 112 of the comparator 110. When the voltage of the first capacitive element 120 (voltage at the first input 112) reaches the reference voltage, the comparator 110 triggers and outputs a high level at the output 116. As described above, in response to the high level at the output 116, the switch 144 switches and couples the second capacitive element 130 to the first input 112 of the comparator 110. The second capacitive element 130 being previously discharged, the voltage on the first input 112 of the comparator 110 would thus be GND and be lower than the reference voltage. In response, the comparator outputs a low level at output 116 (at B), while the current source 150 charges the second capacitive element 130 (at C). As shown in the timing diagram 210, the oscillating signal at the output 116 of the comparator 110 cycles at a period T. In other words, the oscillating signal at the output 116 of the comparator 110 oscillates at a frequency 1/T.

For various reasons, the comparator 110 may trigger at a triggering voltage that is different from the reference voltage. For example, process variation may cause a mismatch of the first input 112 and the second input 114 of the comparator 110. Moreover, the delay of the comparator 110 likewise may cause errors in the trigger voltage. As a result, the comparator 110 may trigger (e.g., outputting a high level at the output 116) at a triggering voltage that is higher than the reference voltage. The exemplary embodiment described by this disclosure removes the trigger voltage overshoot arising from the process variation and the comparator delay. The timing diagrams 220 and 230 illustrate such example. In the timing diagram 220, the comparator 110 triggers (outputting a high level at the output 116) at a triggering voltage that is higher than the reference voltage by a voltage V_{ERR}. As illustrated in the timing diagram 230, the trigger voltage being different from the reference voltage results in the oscillating signal having a period of T+T_{ERR}. In other words, the oscillating signal at the output 116 of the comparator 110 oscillates at a frequency 1/(T+T_{ERR}).

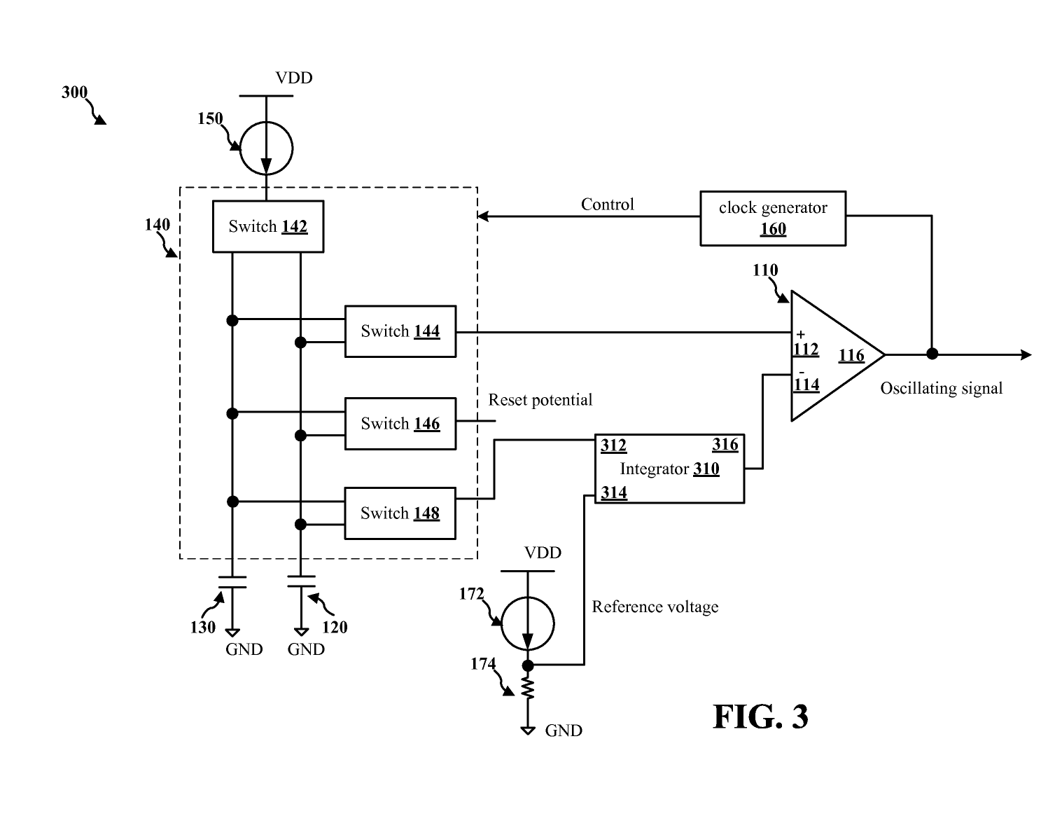

FIG. 3 is a functional block diagram 300 of an exemplary switched-capacitor RC oscillator. Features flowing from an exemplary switched-capacitor RC oscillator address or reduce the oscillation frequency variation described above. The exemplary switched-capacitor RC oscillator includes an integrator 310 having a first input 312, a second input 314, and an output 316 coupled to the second input 114 of the comparator 110. The reference voltage is provided to the second input 314 of the integrator 310 and therefore, couples to the comparator 110 via the integrator 310. The switch 148 alternately couples the first capacitive element 120 and the second capacitive element 130 to the first input 312 of the integrator 310.

The integrator 310 performs integration based on the voltage at the first input 312 (the voltage of the first capacitive element 120 or the voltage of the second capacitive element 130) and the voltage at the second input 314 (reference voltage). For example, the integrator 310 integrates a difference between the voltages at the first input 312 and the second input 314. In one configuration, the integrator 310 outputs, at the output 316, the voltage at the first input 312 subtracted by the integrated difference between the voltage at the first input 312 and the second input 314 (reference voltage) over time. The operation of the integrator 310 in this example may be described by the following equation:

V_{O}=V_{IN2}−∫(V_{IN1}−V_{IN2}),

where V_{O} is the voltage level at the output 316 (provided to the comparator 110), V_{IN1} is the voltage level at the first input 312 (the voltage at the first capacitive element 120 or the voltage at the second capacitive element 130 provided by the switch 148), and V_{IN2} is the voltage level at the second input 314 (reference voltage). For each cycle, the V_{O} is based on the V_{O} of the previous cycle. That is, in a current cycle, the comparator 110 compares the voltage at the first input 112 (the voltage at the first capacitive element 120 or the voltage at the second capacitive element 130 provided by the switch 144) with the voltage at the second input 114 (current V_{O}). In the subsequent cycle, the voltage at the first input 112 (the voltage at the first capacitive element 120 or the voltage at the second capacitive element 130 provided by the switch 144) is then provided to the integrator 310 as V_{IN1} to generate the V_{O} of the subsequent cycle. Thus, over multiple iterations, V_{O} will converge at approximately the reference voltage subtracted by V_{ERR}, and V_{IN1} (which corresponds to the actual trigger voltage in FIG. 2) will converge at approximately the reference voltage.

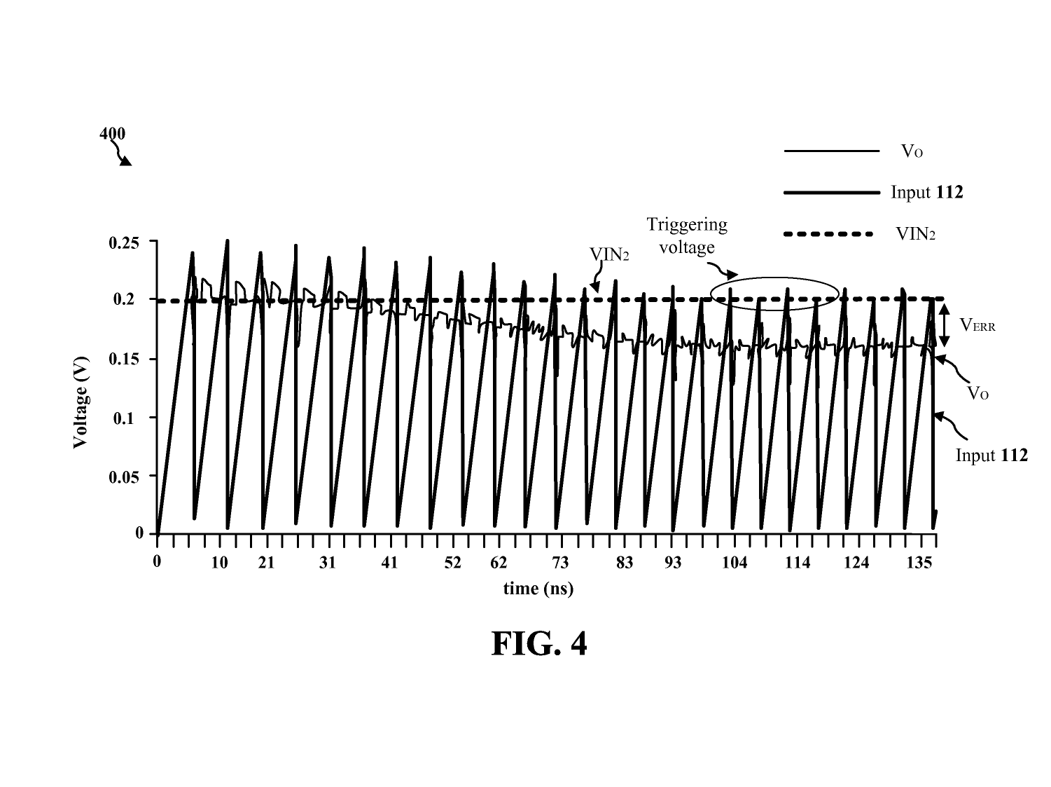

FIG. 4 is a waveform diagram 400 of an exemplary switched-capacitor RC oscillator. FIG. 4 illustrates that, over multiple iterations, V_{O} converges at approximately the reference voltage (V_{IN2}) subtracted by a V_{ERR}. The triggering voltage at the first input 112 of the comparator 110 converges at approximately the reference voltage (V_{IN2}). As illustrated, the exemplary switched-capacitor RC oscillator addresses the issue of errors in the triggering voltage and therefore, inaccuracy in the oscillating signal frequency caused by a comparator.

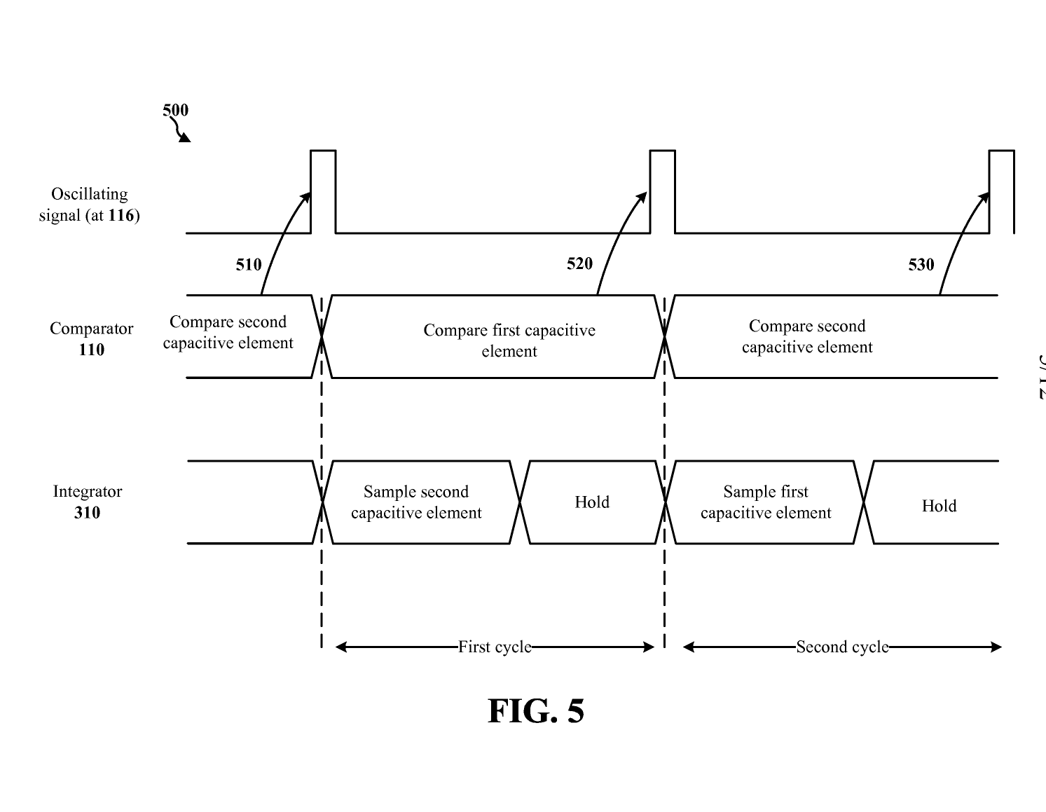

FIG. 5 is an operation mode diagram 500 of an exemplary switched-capacitor RC oscillator. The exemplary switched-capacitor RC oscillator is further configured to provide a stable operation and fast convergence. Signal switching in a switched-capacitor RC oscillator may introduce unwanted noises. Accordingly, the exemplary switched-capacitor RC oscillator samples and holds V_{IN1} at the first input 312 of the integrator 310 continuously in a cycle (e.g., holding the voltage for the duration of a cycle. The comparator 110 alternately compares the voltage of the first capacitive element 120 and the voltage of the second capacitive element 130. FIG. 5 illustrates a first cycle and a subsequent second cycle. Prior to the first cycle, the switch 144 couples the voltage of the second capacitive element 130 to the first input 112 of the comparator 110, and the comparator 110 compares the voltage of the second capacitive element 130 to the voltage at the second input 114 (e.g., V_{O} provided by the integrator 310). When the voltage of the second capacitive element 130 reaches the triggering voltage and exceeds the voltage at the second input 114 of the comparator 110 (e.g., V_{O} provided by the integrator 310), the comparator 110 triggers and outputs a pulse of the oscillating signal at the output 116 (at 510).

At the first cycle, the comparator switches to compare the voltage of the first capacitive element 120 to the voltage at the second input 114. This may be accomplished by the switch 144 switching and coupling the voltage of the first capacitive element 120 to the first input 112 of the comparator 110. When the voltage of the first capacitive element 120 reaches the triggering voltage and exceeds the voltage at the second input 114 of the comparator 110 (e.g., V_{O} provided by the integrator 310), the comparator 110 triggers and outputs a pulse of the oscillating signal at the output 116 (at 520).

Moreover, in the first cycle, the switch 148 switches and couples the voltage of the second capacitive element 130 (which is at the triggering voltage at 510) to the first input 312 of the integrator 310. The integrator 310 samples or captures the voltage of the second capacitive element 130 and performs the integration function as described above. The integrator 310 then provides the integration result (V_{O}) to the second input 114 of the comparator 116. At a later portion of the first cycle, the integrator 310 holds the sampled voltage (and therefore, the output 316 of the integrator 310 also remains stable) for the duration of the first cycle. In one example, the holding of the sampled voltage is provided by the switch 148 switching and decoupling the second capacitive element 130 from the first input 312 of the integrator 310. In one configuration, during the hold period, the switch 146 switches and couples the second capacitive element 130 (now decoupled from the integrator 310) to the reset voltage (e.g., ground or GND) to discharge the second capacitive element 130.

The comparator 110 generating a pulse of the oscillating signal at 520 starts the second cycle. At the second cycle, the comparator 110 switches to compare the voltage of the second capacitive element 130 to the voltage at the second input 114 (e.g., V_{O} provided by the integrator 310). This may be accomplished by the switch 144 switching and coupling the voltage of the second capacitive element 130 to the first input 112 of the comparator 110. When the voltage of the second capacitive element 130 reaches the triggering voltage and exceeds the voltage at the second input 114 of the comparator 110 (e.g., V_{O} provided by the integrator 310), the comparator 110 triggers and outputs a pulse of the oscillating signal at the output 116 (at 530).

Moreover, in the second cycle, the switch 148 switches and couples the voltage of the first capacitive element 120 (which is at the triggering voltage at 520) to the first input 312 of the integrator 310. The integrator 310 samples or captures the voltage of the first capacitive element 120 and performs the integration function as described above. The integrator 310 then provides the integration result (V_{O}) to the second input 114 of the comparator 116. At a later portion of the second cycle, the integrator 310 holds the sampled voltage (and therefore, the output at output 316) for the duration of the second cycle. In one example, the holding is configured by the switch 148 switching and decoupling the first capacitive element 120 from the first input 312 of the integrator 310. In one example, the holding of the sampled voltage is provided by the switch 148 switching and decoupling the first capacitive element 120 from the first input 312 of the integrator 310. In one configuration during the hold period, the switch 146 switches and couples the first capacitive element 120 (now decoupled from the integrator 310) to the reset voltage (e.g., ground or GND) to discharge the first capacitive element 120.

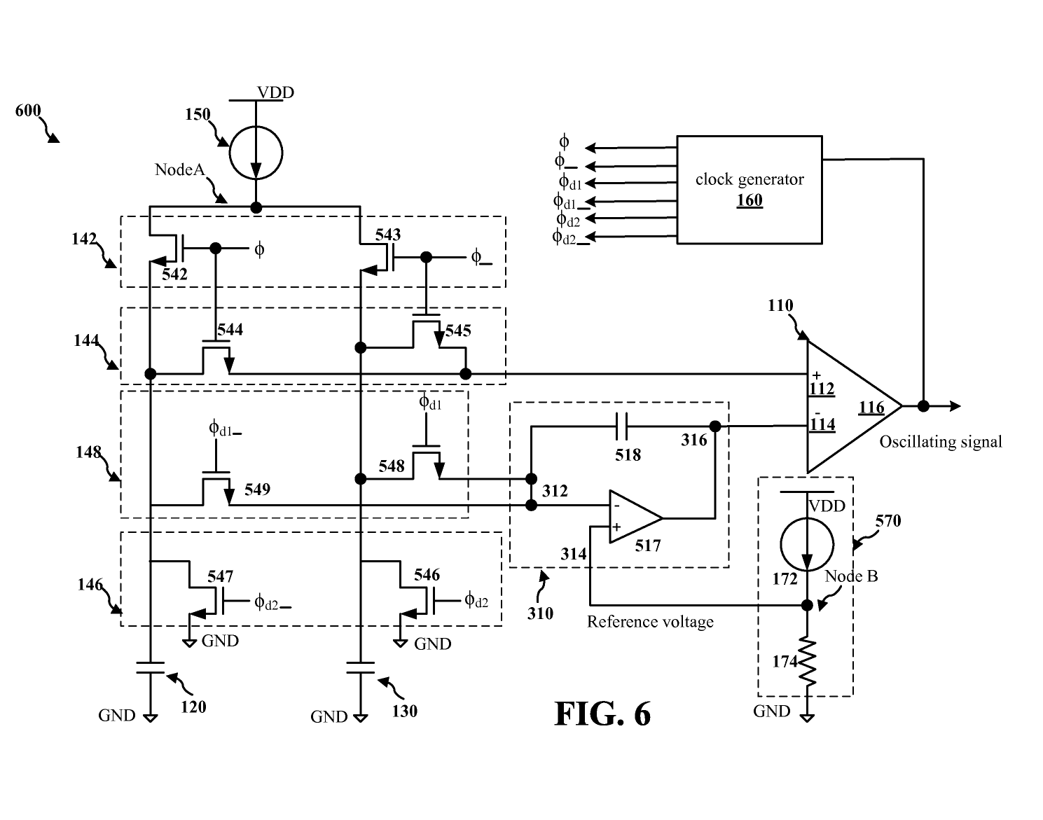

FIG. 6 is a circuit diagram 600 of an exemplary switched-capacitor RC oscillator. The circuit diagram 600 may be viewed as an example of the functional block diagram illustrated in FIG. 3. In the exemplary switched-capacitor RC oscillator, the switch 142 includes an N-type metal-oxide-semiconductor (NMOS) transistor 542 controlled by a clock φ. When activated by the clock φ, the transistor 542 couples the current source 150 to the first capacitive element 120 (via the node A) to charge the first capacitive element 120. In one implementation, a nominal charging time T is R multiplied by C, where R is the resistance of the resistor 174 (for generating the reference voltage), and C is the capacitance of the first capacitive element 120 (or the second capacitive element 130). The switch 142 further includes an NMOS transistor 543 controlled by a clock φ_. When activated by the clock φ_, the transistor 542 couples the current source 150 to the second capacitive element 130 to charge the second capacitive element 130. The charging time is subject to an RC constant according to the resistance of the current source 150 and the capacitance of the second capacitive element 130.

In the exemplary switched-capacitor RC oscillator, the switch 144 includes an NMOS transistor 544 controlled by the clock φ. When activated by the clock φ, the transistor 544 couples the first input 112 of the comparator 110 to the first capacitive element 120, thereby providing the voltage of the first capacitive element 120 to the comparator 110 for comparison with the voltage on the second input 114 (V_{O} provided by the integrator 310) of the comparator 110. The switch 144 further includes an NMOS transistor 545 controlled by the clock φ_. When activated by the clock φ_, the transistor 545 couples the first input 112 of the comparator 110 to the second capacitive element 130, thereby providing the voltage of the second capacitive element 130 to the comparator 110 for comparison with the voltage on the second input 114 (V_{O} provided by the integrator 310) of the comparator 110.

In the exemplary switched-capacitor RC oscillator, the switch 146 includes an NMOS transistor 546 controlled by a clock φ_{d2}. When activated by the clock φ_{d2}, the transistor 546 couples a reset voltage (such as ground or GND) to the second capacitive element 130 to discharge the voltage of the second capacitive element 130 to ground. The switch 146 further includes an NMOS transistor 547 controlled by the clock φ_{d2}_{_{—}}. When activated by the clock φ_{d2}_{_{—}}, the transistor 547 couples a reset voltage (such as ground or GND) to the first capacitive element 120 to discharge the voltage of the first capacitive element 120 to ground.

In the exemplary switched-capacitor RC oscillator, the switch 148 includes an NMOS transistor 548 controlled by a clock φ_{d1}. When activated by the clock φ_{d1}, the transistor 548 couples the first input 312 of the integrator 310 to the second capacitive element 130 to provide the voltage of the second capacitive element 130 to the integrator 310 for integration. The switch 148 further includes an NMOS transistor 549 controlled by a clock φ_{d1}_{_{—}}. When activated by the clock φ_{d1}_{_{—}}, the transistor 549 couples the first input 312 of the integrator 310 to the first capacitive element 120, thereby providing the voltage of the first capacitive element 120 to the integrator 310 for integration.

The integrator 310 may include an operational amplifier 517 and a capacitor 510. The first input 312 of the integrator 310 forms the inverting input (−) of the operational amplifier 517. The second input 314 of the integrator 310 forms the non-inverting input (+) of the operational amplifier 517. A capacitor 518 is coupled to the output 316 and the first input 312, forming a negative feedback of the operational amplifier 517. In operation, a voltage of the first capacitive element 120 or the second capacitive element 130 is put onto the inverting input (−) of the operational amplifier 517, and a difference between that input voltage and the reference voltage at 314 is provided at the output of the operational amplifier 517 by charge transfer. In the subsequent cycle, the comparator 110 compares the voltage of the first capacitive element 120 or the voltage of the second capacitive element 130 to the output voltage V_{O}. As described above, over multiple iterations, the system would converge to stable voltages where the triggering voltage approximately equals to the reference voltage, and the output voltage V_{O} approximately equals to the reference voltage subtracted by the voltage error V_{ERR}.

In the exemplary switched-capacitor RC oscillator, the comparator 110 may be an operational amplifier having a non-inverting input 112, an inverting input 114, and an output 116 outputting the oscillating signal. The exemplary switched-capacitor RC oscillator may further include the clock generator 160, which receives the oscillating signal at the output 116 and generates the clocks φ, φ_, φ_{d1}, φ_{d1}_{_{—}}, φ_{d2}, and φ_{d1}_{_{—}}. The clocks control the switching of the switches 142, 144, 146, and 148 described above. In one configuration, the exemplary switched-capacitor RC oscillator may include the reference voltage source 570. The reference voltage source 570 includes a current source 172 coupled to the voltage source VDD and a node B. A resistor 174 is coupled to node B and the ground GND. The reference voltage (at node B) is determined by the current provided by the current source 172 and the resistance of the resistor 174, and is outputted as the reference voltage to the integrator 310.

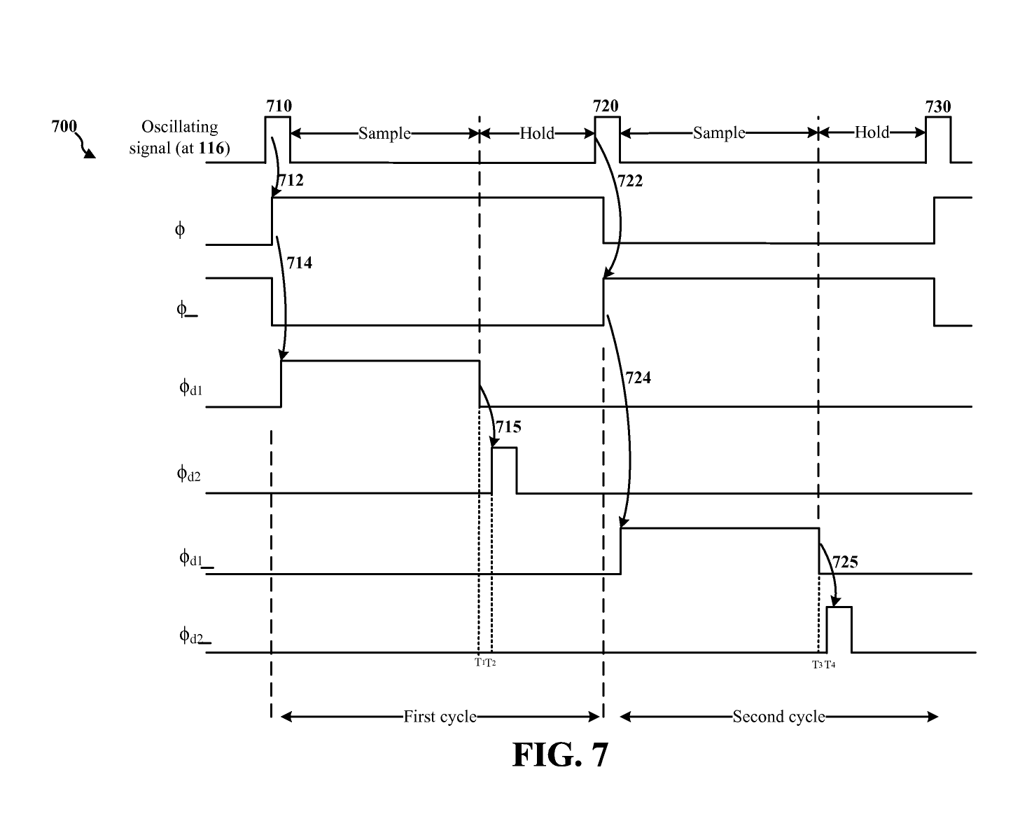

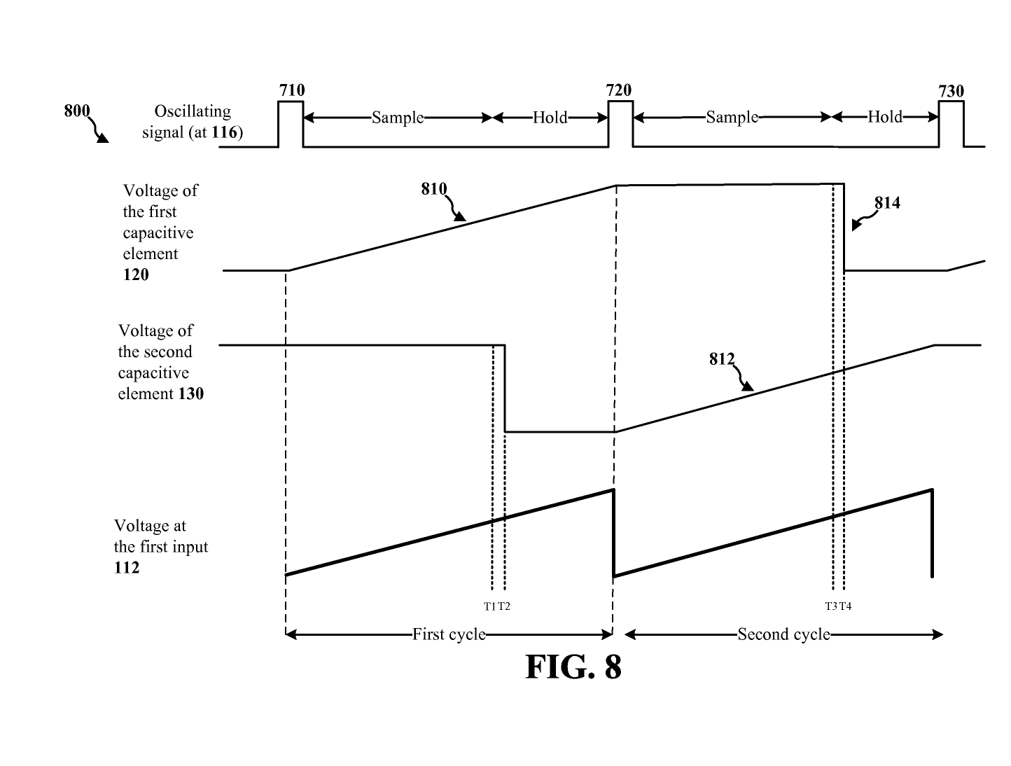

FIG. 7 is a timing diagram 700 illustrating the cycles and clocks of an exemplary switched-capacitor RC oscillator. The clocks include clock φ, φ_, φ_{d1}, φ_{d1}_{_{—}}, φ_{d2}, and φ_{d1}_{_{—}}. FIG. 8 is a timing diagram 800 of an exemplary switched-capacitor RC oscillator illustrating the cycles and the voltages of the first capacitive element 120, the second capacitive element 130, and the first input 112 of the comparator 110. Each of the first cycle and the second cycle includes a sample portion and a hold portion. The clocking signals φ, φ_, φ_{d1}, φ_{d1}_{_{—}}, φ_{d2}, and φ_{d1}_{_{—}} may be generated by the clock generator 160 in accordance with the knowledge of a person of ordinary skill in the art. Before the first cycle, a pulse 710 is generated based on the action the previous cycle.

The pulse 710 causes the clock st to activate (goes high) and its complementary clock φ_ to deactivate (goes low), initiating the first cycle (712). The transistor 542 is turned on by the clock φ. Upon being turn on, the transistor 542 couples the current source 150 to the first capacitive element 120 and charges the first capacitive element 120. The transistor 544 is also turned on by the clock φ, and couples the first input 112 of the comparator 110 to the first capacitive element 120 and for comparison. The clock φ_ deactivates and turns off the transistors 543 and 545, which decouples the second capacitive element 130 from the current source 150 and the first input 112 of the comparator 110.

In the first cycle, the clock φactivates and causes the clock φ_{d1} to activate (714). The clock φ_{d1} is activated for a pulse of a predetermined duration (to time T₁), then deactivates. The clock generator 160 may generate the clock φ_{d1} of a predetermined duration using a delay. For example, the delay may be generated using current-starved transistors driving a capacitive load. The clock φ_{d1} activates and couples the second capacitive element 130 to the first input 312 of the integrator 310, which allows the integrator 310 to sample the voltage of the second capacitive element 130 in this time period. The integrator 310 performs the integration process based on the voltage of the second capacitive element 130 and the reference voltage in the cycle as described above, and provides the integration output to the comparator 110 by way of the second input 114 of the comparator 110.

When the clock φ_{d1} deactivates at time T₁, the second capacitive element 130 is decoupled from the first input 312 of the integrator 310. The integrator 310 holds the voltage inputted at the first input 312 (e.g., across the capacitor 518). Thus, the integrator 310 samples and holds the voltage of the second capacitive element 130 (received at the first input 312 of the integrator 310) continuous for the duration of the first cycle. Because the inputs of the integrator 310 are stable for the cycle, the output 316 of the integrator 310 is likewise stable and is provided to the comparator 110 (the second input 114) continuously for the duration of the first cycle.

The clock φ_{d1} deactivates and causes the clock generator 160 to activate the clock φ_{d2} as a pulse at time T₂. The clock φ_{d2} activates and turns on the transistor 546, which couples the second capacitive element 130 to the reset voltage or GND. The second capacitive element 130 is thus discharged to ground in the first cycle.

As illustrated in FIG. 8, in the first cycle, the voltage of the first capacitive element 120 is charged by the current source 150 via the transistor 542 (810), and is provided to the first input 112 of the comparator 110 by the transistor 544 (switch 144). The charging duration lasts until the voltage of the first capacitive element 120 reaches the triggering voltage and exceeds the voltage at the second input 114 of the comparator 110 (V_{O} provided by the integrator 310). In response, the comparator 110 triggers and outputs the pulse 720 for the first cycle. The pulse 720 activates and causes the switch 144 (transistors 544 and 545) to switch and to couple the second capacitive element 130 to the first input 112 of the comparator 110. Since the second capacitive element 130 is discharged in the first cycle, the comparator 110 outputs a low level, and the pulse 720 terminates.

Referring back to FIG. 7, the pulse 720 causes the clock φ_ to activate and its complementary clock φ to deactivate, which initiates the second cycle (722). The transistor 543 is turned on by the clock φ_. Upon being turned on, the transistor 543 couples the current source 150 to the second capacitive element 130. The current source 150 charges the second capacitive element 130 via the transistor 543. The transistor 545 is also turned on by the clock φ_. Upon being turned on, the transistor 545 couples the first input 112 of the comparator 110 to the second capacitive element 130 for comparison. The clock φ deactivates and turns off the transistors 542 and 544, which decouples the first capacitive element 120 from the current source 150 and the first input 112 of the comparator 110.

In the second cycle, the clock φ_ activates and causes the clock φ_{d1}_{_{—}} to activate (724). The clock φ_{d1}_{_{—}} is activated for a pulse of a predetermined duration (to time T₃), then deactivates. The clock generator 160 may generate the clock φ_{d1}_{_{—}} of a predetermined duration using a delay (e.g., using current-starved transistors). Upon being turn on, the clock φ_{d1}_{_{—}} couples the first capacitive element 120 to the first input 312 of the integrator 310, which allows the integrator 310 to sample the voltage of the first capacitive element 120 in this time period. The integrator 310 performs the integration process based on the voltage of the first capacitive element 120 and the reference voltage in the cycle, as described above, and provides the integration output to the comparator 110 by way of the second input 114 of the comparator 110.

When the clock φ_{d1}_{_{—}} deactivates at time T₃, the first capacitive element 120 is decoupled from the first input 312 of the integrator 310. Upon being decouple from the first capacitive element 120, integrator 310 holds the voltage inputted at the first input 312 (e.g., across the capacitor 518). Thus, the integrator 310 samples and holds the voltage of the first capacitive element 120 (received at the first input 312 of the integrator 310) continuous for the duration of the second cycle. Because the inputs of the integrator 310 are stable, the output 316 of the integrator 310 is likewise stable and is provided to the comparator 110 (the second input 114) continuously for the duration of the second cycle.

The clock φ_{d1}_{_{—}} deactivates and causes the clock generator 160 to activate the clock φ_{d2}_{_{—}} as a pulse at time T₄. The clock φ_{d2}_{_{—}} pulse turns on the transistor 547 and couples the first capacitive element 120 to the reset voltage or ground. The first capacitive element 120 is thus discharged to ground in the second cycle.

As illustrated in FIG. 8, in the second cycle, the voltage of the second capacitive element 130 is charged by the current source 150 via the transistor 543 (at 812), and is provided to the first input 112 of the comparator 110 by the transistor 545 (switch 144). The charging duration lasts until the voltage of the second capacitive element 130 reaches the triggering voltage and exceeds the voltage at the second input 114 of the comparator 110 (V_{O} provided by the integrator 310). In response, the comparator 110 triggers and outputs the pulse 730 for the second cycle (FIG. 7). The pulse 730 causes the switches 142, 144, 146, and 148 to switch and operate as described with the first cycle. At 814 (time T₄) the clock φ_{d2}_{_{—}} pulse turns on the transistor 547 and couples the first capacitive element 120 to the reset voltage or ground. The first capacitive element 120 is thus discharged to ground in the second cycle.

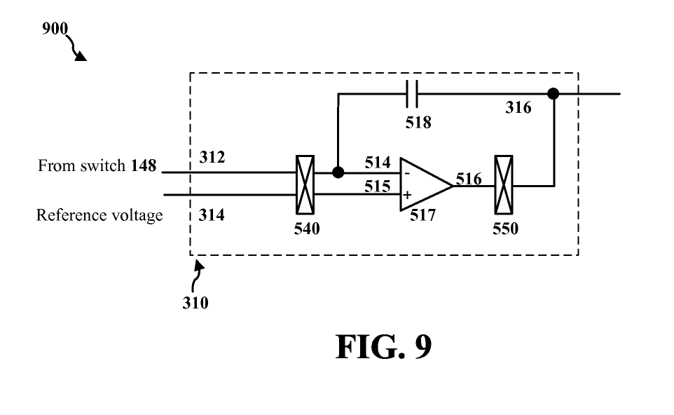

FIG. 9 is a circuit diagram 900 of an exemplary integrator 310. The integrator 310 includes the operational amplifier 517 having a first input (e.g., the inverting input) 514, a second input (e.g., the non-inverting input) 515, and an output 516. The first input 312 and the second input 314 of the integrator 310 are coupled to the first input 514 and the second input 515 via a first chopper circuit 540. The output 316 of the integrator 310 is coupled to the output 516 of the operational amplifier 517 via a second chopper circuit 550. As would be understood by a person of ordinary skill in the art, a chopper circuit may include a switch circuit that switches the polarities of the inputs or outputs of operational amplifiers. For example, the first chopper circuit 540 switches the inputs 312 and 314 of the comparator as inputs to the inputs 514 and 515 of the operational amplifier 517 at a chopping frequency. The second chopper circuit 550 switches the polarities of the output 516 and supplies the result to the output 316 of the integrator 310 at the chopping frequency. The chopping frequency is usually higher than the operating frequency of the integrator 310. A chopping operational amplifier as configured in this integrator provides improved direct current offset and reduces phase noises.

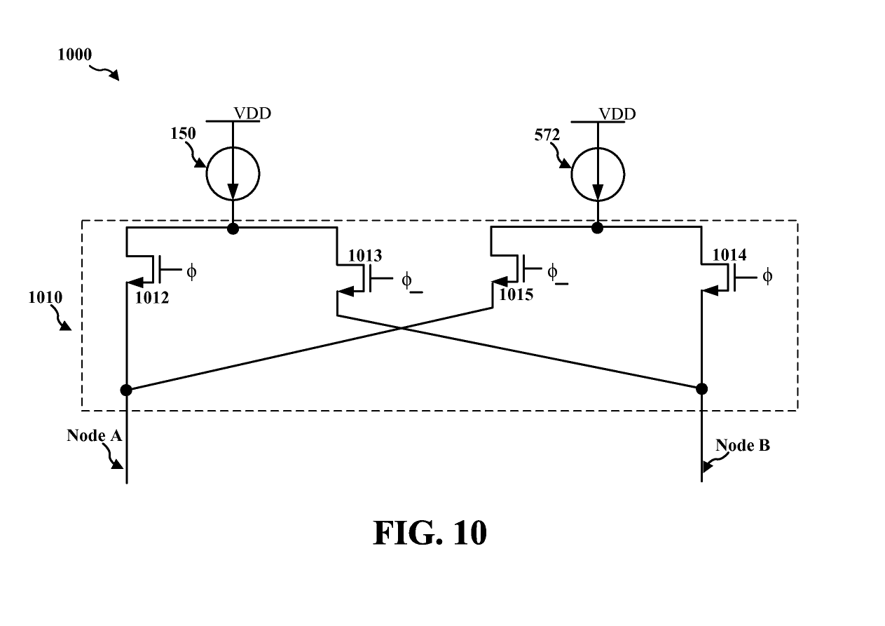

FIG. 10 is a circuit diagram 1000 of an exemplary switch for the current sources. A switch 1010 is disposed between the current source 150 and node A (see FIG. 6; the node A connects to the first capacitive element 120 and the second capacitive element 130), and between the current source 172 and node B of the reference voltage source 570. The switch 1010 includes a transistor 1012 and a transistor 1014 controlled by the clock φ. The switch 1010 further includes a transistor 1013 and 1015 controlled by the clock φ_. The transistor 1012 (when in the on state) couples the current source 150 to the node A. The transistor 1013 (when in the on state) couples the current source 150 to the node B. The transistor 1015 (when in the on state) couples the current source 172 to the node A. The transistor 1014 (when in the on state) couples the current source 172 to the node B.

In the first cycle, clock φactivates and turns on the transistors 1012 and 1014. The clock φ_ deactivates and turns off the transistors 1013 and 1015. In this configuration, the current source 150 charges one of the capacitive elements 120 and 130, and the current source 172 supplies the reference voltage. In the second cycle, the configuration is reversed. The clock φ_ activates and turns on the transistors 1013 and 1015. The clock φ deactivates and turns off the transistors 1012 and 1014. In this configuration, the current source 172 charges one of the capacitive elements 120 and 130, and the current source 150 supplies the reference voltage. By switching the current sources, the error caused by the discrepancy between the current source 150 and the current source 172 may be minimized. By alternating the current supplies, the polarities of the errors caused by the discrepancy between the current source 150 and the current source 172 may be alternately subtracted instead of being integrated in over the cycles.

As described above, the current source 150 may provide the means for charging a first capacitive element 120 in a cycle and a second capacitive element 130 in a subsequent cycle. The integrator 310 may provide the means for sampling and holding a voltage of the second capacitive element 130 continuously in the cycle, and sampling and holding a voltage of the first capacitive element 120 continuously in the subsequent cycle. The integrator 310 may further provide the means for integrating based on the voltage of the second capacitive element 130 and the reference voltage in the cycle, and integrating based on the voltage of the first capacitive element and the reference voltage in the subsequent cycle. The integrator 310 may be configured to integrate a difference between the voltage of the first capacitive element 120 and the reference voltage of the reference voltage source 570 in the cycle. The integrator 310 may further be configured to provide an output of the integration continuously to the second input 114 of the comparator 110.

The comparator 110 may provide the means for comparing the voltage of the first capacitive element 120 to an output of the integration (e.g., at the output 316 of the integrator 310) in the cycle and for comparing the voltage of the second capacitive element 130 to the output of the integration in the subsequent cycle. The comparator 110 may further provide the means for generating a first pulse 720 of an oscillating signal based on a result of the comparison in the cycle, and for generating a second pulse 730 of the oscillating signal based on the result of the comparison in the subsequent cycle.

The switch circuit 140, and in particular the switch 142, may provide the means for coupling the current source 150 to the first capacitive element 120 to charge the first capacitive element 120 in the cycle, and provide the means for coupling the current source 150 to the second capacitive element 130 to charge the second capacitive element in the subsequent cycle.

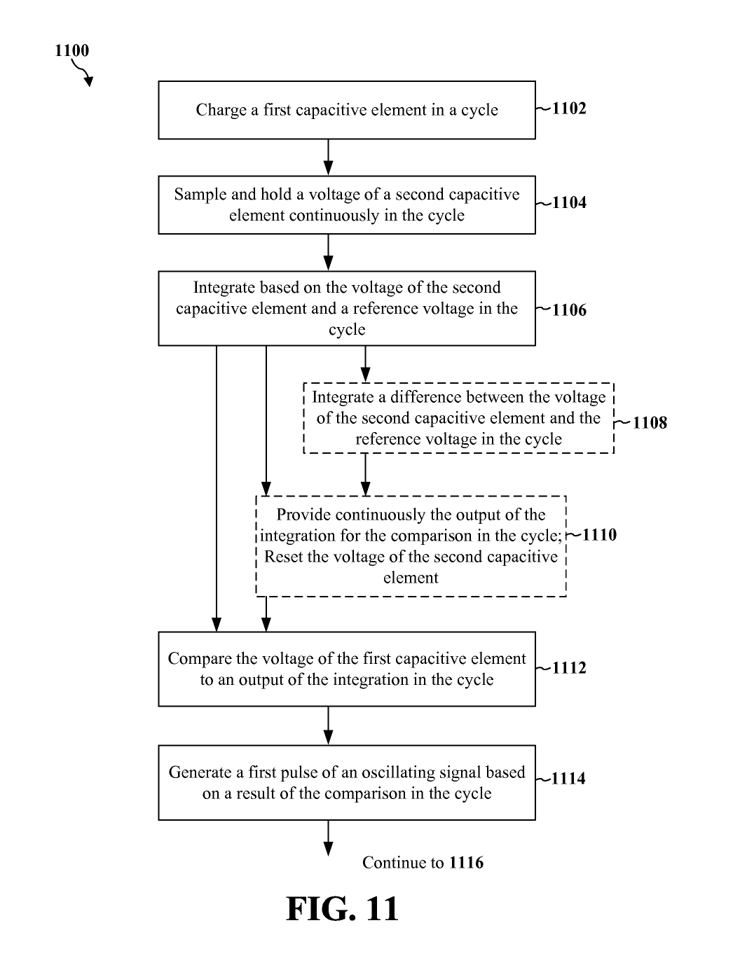

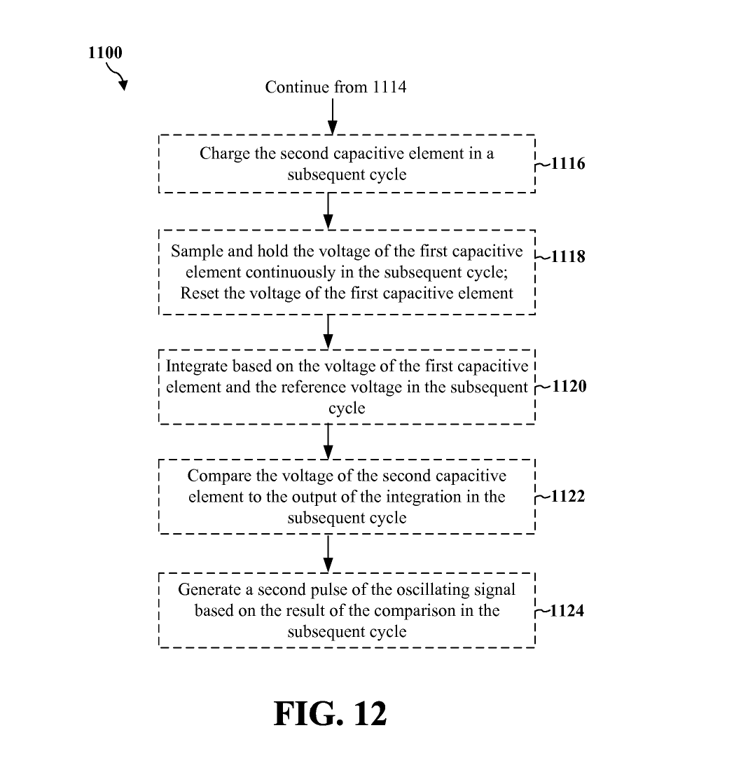

FIG. 11 is a first portion of a flowchart 1100 of the exemplary switched-capacitor RC oscillator for generating an oscillating signal. FIG. 12 is the second portion of a flowchart 1110 of an exemplary switched-capacitor RC oscillator for generating the oscillating signal. The steps shown in dotted lines may be optional. At 1102, a first capacitive element is charged in a cycle. For example, referring to FIGS. 6-8, the pulse 710 causes the clock φ to activate and its complementary clock φ_ to deactivate, which initiates the first cycle (712). The transistor 542 is turned on by the clock φ, and couples the current source 150 to the first capacitive element 120. The current source 150 charges the first capacitive element 120.

At 1104, a voltage of a second capacitive element is sampled and held continuously in the cycle. For example, referring to FIG. 7, when the clock φ_{d1} deactivates at time T₁, the second capacitive element 130 is decoupled from the first input 312 of the integrator 310. The integrator 310 holds the voltage inputted at the first input 312 (e.g., across the capacitor 518). Thus, the integrator 310 samples and holds the voltage of the second capacitive element 130 (received at the first input 312 of the integrator 310) continuous for the duration of the first cycle. Because the inputs of the integrator 310 are stable for the cycle, the output 316 of the integrator 310 is likewise stable and is provided to the comparator 110 (the second input 114) continuously for the duration of the first cycle.

At 1106, integration is performed based on the voltage of the second capacitive element and a reference voltage in the cycle. At 1108, a difference between the voltage of the second capacitive element and the reference voltage in the cycle is integrated. For example, referring to FIGS. 6-8, the clock φd1 activates and couples the second capacitive element 130 to the first input 312 of the integrator 310, which allows the integrator 310 to sample the voltage of the second capacitive element 130 in this time period. The integrator 310 performs the integration process based on the voltage of the second capacitive element 130 and the reference voltage in the cycle and provides the integration output to the comparator 110 by way of the second input 114 of the comparator 110. Further, referring to FIG. 3, the integrator 310 performs integration based on the voltage at the voltages at the first input 312 and the second input 314. For example, the integrator 310 integrates the difference between the voltages at the first input 312 and the second input 314. In one configuration, the integrator 310 outputs at the output 316 the voltage at the first input 312 subtracted by the integrated difference between the voltage at the first input 312 and the second input 314 (reference voltage) over time. The operation of the integrator 310 in this example may be described by the following equation:

V_{O}=V_{IN2}−∫(V_{IN1}−V_{IN2}),

where V_{O} is the voltage level at the output 316 (provided to the comparator 110), V_{IN1} is the voltage level at the first input 312 (the voltage at the first capacitive element 120 or the voltage at the second capacitive element 130 provided by the switch 148), and V_{IN2} is the voltage level at the second input 314 (reference voltage). For each cycle, the V_{O} is based on the V_{O} of the previous cycle. That is, in a current cycle, the comparator 110 compares the voltage at the first input 112 (the voltage at the first capacitive element 120 or the voltage at the second capacitive element 130 provided by the switch 144) with the voltage at the second input 114 (current V_{O}). In the subsequent cycle, the voltage at the first input 112 (the voltage at the first capacitive element 120 or the voltage at the second capacitive element 130 provided by the switch 144) is then provided to the integrator 310 as V_{IN1} to generate the V_{O} of the subsequent cycle. Thus, over multiple iterations, V_{O} will converge at approximately the reference voltage subtracted by V_{ERR}, and V_{IN1} (which corresponds to the actual trigger voltage in FIG. 2) will converge at approximately the reference voltage.

At 1110, the output of the integration is provided continuously for the comparison in the cycle. For example, referring to FIGS. 6-8, when the clock φ_{d1} deactivates at time T₁, the second capacitive element 130 is decoupled from the first input 312 of the integrator 310. The integrator 310 holds the voltage inputted at the first input 312 (e.g., across the capacitor 518). Thus, the integrator 310 samples and holds the voltage of the second capacitive element 130 (received at the first input 312 of the integrator 310) continuous for the duration of the first cycle. Because the inputs of the integrator 310 are stable, the output of the integrator 310 is likewise stable and is provided to the comparator 110 (the second input 114) continuously for the duration of the first cycle. The step 1110 may further include resetting the voltage of the second capacitive element. See, e.g., FIG. 8 at time T₂. At time T₂, the clock φ_{d2} activates and turns on the transistor 546, which couples the second capacitive element 130 to the reset voltage or GND. The second capacitive element 130 is thus discharged to ground in the first cycle.

At 1112, the voltage of the first capacitive element is compared to an output of the integration in the cycle. At 1114, a first pulse of an oscillating signal is regenerated based on a result of the comparison in the cycle. For example, referring to FIGS. 6-8, the voltage of the first capacitive element 120 is charged by the current source 150 via the transistor 542 in the first cycle. The charging lasts until the voltage of the first capacitive element 120 reaches and exceeds the voltage at the second input 114 of the comparator 110 (V_{O} provided by the integrator 310). In response, the comparator 110 triggers and outputs the pulse 720 for the first cycle. The pulse 720 causes the switch 144 (transistors 544 and 545) to switch and to couple the second capacitive element 130 to the first input 112 of the comparator 110. Since the second capacitive element 130 is discharged in the first cycle, the pulse 720 terminates.

At 1116, a second capacitive element is charged in a subsequent cycle. For example, referring to FIGS. 6-8, the pulse 710 causes the clock φ_ to activate and its complementary clock φ to deactivate, which initiates the second cycle (722). The transistor 543 is turned on by the clock φ_. Upon being turned on, the transistor 543 couples the current source 150 to the second capacitive element 130. The current source 150 charges the second capacitive element 130 via the transistor 543. The transistor 545 is also turned on by the clock φ_. Upon being turned on, the transistor 545 couples the first input 112 of the comparator 110 to the second capacitive element 130 for comparison. The clock φ deactivates and turns off the transistors 542 and 544, which decouples the first capacitive element 120 from the current source 150 and the first input 112 of the comparator 110.

At 1118, the voltage of the first capacitive element is sampled and held continuously in the subsequent cycle. For example, referring to FIGS. 6-8, when the clock φ_{d1}_{_{—}} deactivates at time T3, the first capacitive element 120 is decoupled from the first input 312 of the integrator 310. The integrator 310 holds the voltage inputted at the first input 312 (e.g., across the capacitor 518). Thus, the integrator 310 samples and holds the voltage of the first capacitive element 120 (received at the first input 312 of the integrator 310) continuous for the duration of the second cycle. Because the inputs of the integrator 310 are stable, the output of the integrator 310 is likewise stable and is provided to the comparator 110 (the second input 114) continuously for the duration of the second cycle. Step 1118 may further include resetting the voltage of the first capacitive element. See, e.g., FIG. 8 at 814. At 814 (time T₄) the clock φ_{d2}_{_{—}} pulse turns on the transistor 547 and couples the first capacitive element 120 to the reset voltage or ground. The first capacitive element 120 is thus discharged to ground in the second cycle.

At 1120, integration is performed based on the voltage of the first capacitive element and the reference voltage in the subsequent cycle. For example referring to FIGS. 6-8, the clock φ_{d1}_{_{—}} is activates, and the first capacitive element 120 is coupled to the first input 312 of the integrator 310. The integrator 310 samples the voltage of the first capacitive element 120 in this time period. The integrator 310 performs the integration process and provides the integration output to the comparator 110 by way of the second input 114 of the comparator 110. Further, referring to FIG. 3, the integrator 310 performs integration based on the voltage at the voltages at the first input 312 and the second input 314. For example, the integrator 310 integrates a difference between the voltages at the first input 312 and the second input 314. In one configuration, the integrator 310 outputs at the output 316 the voltage at the first input 312 subtracted by the integrated difference between the voltage at the first input 312 and the second input 314 (reference voltage) over time. The operation of the integrator 310 in this example may be described by the following equation:

V_{O}=V_{IN2}−∫(V_{IN1}−V_{IN2}),

Where V_{O} is the voltage level at the output 316 (provided to the comparator 110), V_{IN1} is the voltage level at the first input 312 (the voltage at the first capacitive element 120 or the voltage at the second capacitive element 130 provided by the switch 148), and V_{IN2} is the voltage level at the second input 314 (reference voltage). For each cycle, the V_{O} is based on the V_{O} of the previous cycle. That is, in a current cycle, the comparator 110 compares the voltage at the first input 112 (the voltage at the first capacitive element 120 or the voltage at the second capacitive element 130 provided by the switch 144) with the voltage at the second input 114 (V_{O} of current cycle). In the subsequent cycle, the voltage at the first input 112 (the voltage at the first capacitive element 120 or the voltage at the second capacitive element 130 provided by the switch 144) is then provided to the integrator 310 as V_{IN1} to generate the V_{O} of the subsequent cycle. Thus, over multiple iterations, V_{O} will converge at approximately the reference voltage subtracted by V_{ERR}, and V_{IN1} (which corresponds to the actual trigger voltage in FIG. 2) will converge at approximately the reference voltage.

At 1122, the voltage of the second capacitive element is compared to the output of the integration in the subsequent cycle. At 1124, a second pulse of the oscillating signal based on the result of the comparison is generated in the subsequent cycle. For example referring to FIGS. 6-8, the voltage of the second capacitive element 130 is charged by the current source 150 via the transistor 543 in the second cycle. The charging lasts until the voltage of the second capacitive element 130 reaches and exceeds the voltage at the second input 114 of the comparator 110 (V_{O} provided by the integrator 310). In response, the comparator 110 triggers and outputs the pulse 730 for the second cycle. The activation of pulse 730 causes the switches 142, 144, 146, and 148 to switch and operate as the first cycle

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A resistance capacitance (RC) oscillator, comprising:
a first capacitive element and a second capacitive element;
a comparator having a first input, a second input, and an output for outputting an oscillating signal;
an integrator having a first input, a second input coupled to a reference voltage source, and an output coupled to the second input of the comparator; and
a switch circuit configured to provide a voltage of the first capacitive element to the first input of the comparator in a cycle and a voltage of the second capacitive element to the first input of the comparator in a subsequent cycle,
wherein the integrator is configured to sample and to hold the voltage of the second capacitive element continuously in the cycle.

2. The RC oscillator of claim 1, wherein the comparator is configured to compare the voltage of the first capacitive element with the output of the integrator to generate a first pulse of the oscillating signal in the cycle, and to compare the voltage of the second capacitive element with the output of the integrator to generate a second pulse of the oscillating signal in the subsequent cycle, and
the switch circuit is further configured to provide the voltage of the second capacitive element to the first input of the integrator in the cycle and the voltage of the first capacitive element to the first input of the integrator in the subsequent cycle.

3. The RC oscillator of claim 2, wherein the integrator is configured in part to integrate a difference between the voltage of the second capacitive element and a reference voltage of the reference voltage source in the cycle.

4. The RC oscillator of claim 2, wherein the integrator is configured to provide an output of the integration continuously to the second input of the comparator.

5. The RC oscillator of claim 2, further comprising a current source, wherein the switch circuit is further configured to couple the current source to the first capacitive element to charge the first capacitive element in the cycle, and to couple the current source to the second capacitive element to charge the second capacitive element in the subsequent cycle.

6. The RC oscillator of claim 5, further comprising a reset voltage source, wherein the switch circuit is further configured to couple the second capacitive element to the reset voltage source to discharge the second capacitive element in the cycle, and to couple the first capacitive element to the reset voltage source to discharge the first capacitive element in the subsequent cycle.

7. The RC oscillator of claim 2, wherein the integrator further comprises:
an operational amplifier having a first input coupled to the first input of the integrator, a second input coupled to the second input of the integrator, and an output coupled to the output of the integrator; and
a capacitor coupled to the first input and the output of the operational amplifier.

8. The RC oscillator of claim 7, wherein the integrator is configured to sample and the voltage of the second capacitive element at the first input of the operational amplifier in the cycle, and to hold the voltage of the second capacitive element across the capacitor continuously in the cycle.

9. The RC oscillator of claim 8, wherein the reference voltage source further comprises:
a reference voltage current source; and
a reference voltage resistor, where the reference voltage current source is configured to provide a current to the reference voltage resistor to generated the reference voltage.

10. The RC oscillator of claim 9, further comprising a first current source and a second current source,
wherein the switch circuit is configured to couple the first current source to the first capacitive element to charge the first capacitive element in the cycle, and to couple the second current source to the reference voltage source in the cycle, and
configured to couple the second current source to the second capacitive element to charge the second capacitive element in the subsequent cycle, and to couple the first current source to the reference voltage source in the subsequent cycle.

11. A method for operating a resistance capacitance (RC) oscillator, comprising:
charging a first capacitive element in a cycle;
sampling and holding a voltage of a second capacitive element continuously in the cycle;
integrating based on the voltage of the second capacitive element and a reference voltage in the cycle;
comparing a voltage of the first capacitive element to an output of the integration in the cycle; and
generating a first pulse of an oscillating signal based on a result of the comparison in the cycle.

12. The method of claim 11, further comprising:
charging the second capacitive element in a subsequent cycle;
sampling and holding the voltage of the first capacitive element continuously in the SU sequent cycle;
integrating based on the voltage of the first capacitive element and the reference voltage in the subsequent cycle;
comparing the voltage of the second capacitive element to the output of the integration in the subsequent cycle; and
generating a second pulse of the oscillating signal based on the result of the comparison in the subsequent cycle.

13. The method of claim 12, wherein the integrating comprises integrating a difference between the voltage of the second capacitive element and the reference voltage in the cycle.

14. The method of claim 12, further comprising providing continuously the output of the integration for the comparison in the cycle.

15. The method of claim 12, further comprising:
coupling a current source to the first capacitive element to charge the first capacitive element in the cycle; and
coupling the current source Co the second capacitive element to charge the second capacitive element in the subsequent cycle.

16. The method of claim 15, further comprising:
coupling the second capacitive element to a reset voltage source to discharge the second capacitive element in the cycle; and
coupling the first capacitive element to the reset voltage source to discharge the first capacitive element in the subsequent cycle.

17. The method of claim 12, further comprising:
coupling a first current source to the first capacitive element to charge the first capacitive element in the cycle, and coupling a second current source to the reference voltage in the cycle, and
coupling the second current source to the second capacitive element to charge the second capacitive element in the subsequent cycle, and coupling the first current source to the reference voltage in the subsequent cycle.

18. A resistance capacitance (RC) oscillator, comprising:
charging means for charging a first capacitive element in a cycle;
integrating means for sampling and holding a voltage of a second capacitive element continuously in the cycle, and for integrating based on the voltage of the second capacitive element and a reference voltage in the cycle; and
comparing means for comparing a voltage of the first capacitive element to an output of the integration in the cycle and for generating a first pulse of an oscillating signal based on a result of the comparison in the cycle.

19. The RC oscillator of claim 18, wherein
the charging means is further configured for charging the second capacitive element in a subsequent cycle,
the integrating means is further configured for sampling and holding the voltage of the first capacitive element continuously in the subsequent cycle and for integrating based on the voltage of the first capacitive element and the reference voltage in the subsequent cycle,
the comparing means is further configured for comparing the voltage of the second capacitive element to the output of the integration in the subsequent cycle and for generating a second pulse of the oscillating signal based on the result of the comparison in the subsequent cycle.

20. The RC oscillator of claim 19, wherein the integrating means is configured in part to integrate a difference between the voltage of the first capacitive element and the reference voltage in the cycle.

21. The RC oscillator of claim 19, wherein the integrating means is configured to provide an output of the integration continuously to the comparing means.

22. The RC oscillator of claim 19, further comprising switching means for coupling the charging means to the first capacitive element to charge the first capacitive element in the cycle, and for coupling the charging means to the second capacitive element to charge the second capacitive element in the subsequent cycle.
